(19) United States
(12) Patent Application Publication
(10) Pub. No.: US 2010/0094575 A1
(43) Pub. Date: Apr. 15, 2010

(54) METHOD FOR DIAGNOSING THE LEAD-ACID BATTERY OF AN AUTOMOBILE AND SYSTEM FOR IMPLEMENTING THE SAME

(75) Inventors: Olivier Andrieu, Beynost (FR); Laurence Achille, Lyon (FR)

Correspondence Address: DENNISON, SCHULTZ & MACDONALD, 1727 KING STREET, SUITE 105, ALEXANDRIA, VA, 22314, US

(73) Assignee: ELECTRICFIL AUTOMOTIVE, Mirabel CEDEX (FR)

(21) Appl. No.: 12/525,877

(22) PCT Filed: Feb. 15, 2008
(86) PCT No.: PCT/FR2008/050253

§ 371 Date: Sep. 16, 2009

(30) Foreign Application Priority Data
Feb. 16, 2007 (FR) 0753298

(51) Int. Cl. G01R 31/36; G01N 27/416

(52) U.S. Cl. 702/63; 324/427

(57) ABSTRACT

A method for diagnosing a lead-acid battery of an automotive vehicle includes an experimentation phase in which parameterization of the state of health (SOH) of a lead-acid battery for different values of the state of charge (SOC) of the battery is conducted, and a diagnosis phase in which the battery temperature during the start-up phase of the vehicle is measured and, after the first discharge and over a given range of current variation, the corresponding voltage (U) and current (I) is measured, to deduce therefrom after processing, a value of parameter (γ) of the battery. The state of charge (SOC) of the battery is then determined, and the value representing the state of health is determined, so as to establish a diagnosis of the battery.

The present invention concerns the technical area of start-up batteries of lead-acid type.

The subject of the invention finds particularly advantageous, but not exclusive application, to a start-up battery for automotive vehicle.

One of the major causes of immobilization of an automotive vehicle is ill-functioning of the start-up battery. It is therefore necessary to know the functioning status of the battery so that the user can be warned of any battery failure.

In the state of the art, it is known to determine the state of ageing or health of a battery by evaluating the internal resistance of the battery, which is determined by applying an alternate electric signal to the battery terminals. Said principle is difficult to implement for an in-vehicle battery.

For an in-vehicle battery it is known to measure permanently the characteristics of the battery, such as voltage, current and temperature so as to deduce its charge status. In relation to the logging of state of charge, it is possible to deduce the functioning status of the battery. In practice, this method proves to be relatively complex and cumbersome to implement.

Also, an energy management system for the battery of an automotive vehicle is known from document US 2003/025481 capable of determining the state of charge and state of health of the battery on the basis of measurements of voltages, currents and temperatures taken during a forcing phase of the battery. Said system proves to be relatively difficult and costly to use, since said system must be provided with a control module to place the battery in a forced operating phase.

The objective of the invention is therefore to overcome the disadvantages of known technical solutions by proposing a novel method which, in reliable, simple and low-cost manner and through direct use of normal operating points of the vehicle and hence without any particular prompting of the battery, can diagnose a lead-acid battery equipping an automotive vehicle.

To reach this objective, the method of the invention comprises the following steps:

during an experimentation phase, of carrying out parameterization of the state of health of a lead-acid battery for different state of charge values of the battery, for each of the state of charge values there are values representing the state of health of the battery for pairs of values including battery temperature and at least one battery parameter which is determined on the basis of battery voltage and current, the temperature, current and voltage being measured during the vehicle start-up phase over a given range of current variation and after the first discharge,

during a diagnosis phase of the battery equipping the vehicle:
during the start-up phase of the vehicle, of measuring the temperature of the battery and, after the first discharge and over a given range of current variation, of measuring the corresponding voltage and current so as to deduce, after processing, a value of the battery parameter,
of determining the state of charge of the battery,
and of determining the value representing the state of health of the battery using the parameterization and the pair of values of measured temperature and parameter deduced from measurements, for the state of charge, so as to establish a diagnosis of the battery.

By way of example, the values representing the state of health correspond to values of the Ah capacity of the battery or to chemical characteristics of the battery.

Also by way of example, the battery parameter is determined on the basis of characteristics of the battery such as the voltage and current delivered by the battery and their changes over time.

According to one preferred characteristic of embodiment, the battery parameter is determined from characteristics of the battery such as a considered voltage or current value for a threshold voltage and current respectively, a ratio between the peak voltage and current values, a current or voltage value respectively corresponding to a peak voltage or peak current or to changes in voltage and current over time.

According to one preferred characteristic of embodiment, for calculation of the state of health, a distinction is made between the nominal capacity Qn defined as battery capacity when new, and real capacity Qr which takes ageing into account:

Qr(Ah)=(1−% ageing)*Qn(Ah).

According to one preferred characteristic of the invention, the dynamic parameter linked to nominal capacity is calculated from current-voltage characteristics under strong current, and the parameter related to ageing is calculated from current-voltage characteristics under low current.

According to another characteristic of the invention, the nominal capacity may form an input data item for the system (prior calibration) thereby enabling calculation of real capacity by estimating ageing.

According to one preferred variant of embodiment, the method consists of determining the state of charge of the battery from measurement of battery characteristics taken during stoppage of the vehicle, and from matrices giving the percentage state of charge in relation to pairs of voltage and temperature values.

Advantageously, the method consists of taking the measurements after a stoppage time of the vehicle necessary for physicochemical stabilization of the battery.

A further object of the invention is to propose a method allowing determination of the diagnosis of the start-up capability of a lead-acid battery in an automotive vehicle.

To attain this objective, the method of the invention consists of determining the start-up capability of the battery in relation to the value representing state of health.

According to a first variant of embodiment, the method consists of determining the start-up capability of the battery by recording changes in the value representing state of health determined during repeat of the operating phase of the battery, and by providing information on battery start-up capability when the value representing state of health reaches a determined threshold value or when changes come to exceed a determined variation range.

According to one characteristic of the invention, a distinction can be made between two different evaluations of start-up capability, one evaluation at the current functioning cycle and a predictive evaluation which depends on changes in state of charge and temperature.

According to this example, the method consists of determining battery start-up capability by determining a start-up index, in relation to the state of health of the battery, for the parameter value and at the measured temperature.

According to another variant of embodiment, the method consists:

for the value representing state of health and by means of the parameterization, of deducing a value of the parameter at the measured temperature value to which a safety factor is applied and at the determined state of charge to which a safety factor is applied;

establishing a predictive determination of battery start-up capability in relation to the value of the battery parameter and to changes in battery operating conditions.

According to this example, the method consists of calculating the start-up index on several occasions during the battery operating phase, and of monitoring changes in this index to provide a diagnosis on the start-up capability of the battery.

Advantageously, in relation to the start-up index, the method consists of providing information either on problem-free start-up, or on difficult start-up, or on impossible start-up.

Preferably, for a difficult start-up index, the method consists of providing information on recommended heating, charging or change of battery.

For example, for a difficult start-up index, the method consists of recommending:

charging the battery if the state of charge is low

changing the battery if state of charge is high.

A further objective of the invention is to propose a system for implementing the diagnosis method according to the invention.

To reach this objective, in a casing equipped with assembly means, the system comprises:

a sensor to measure the current delivered by the battery,

a sensor to measure battery voltage,

a sensor to measure battery temperature,

an acquisition and processing unit linked to the measuring sensors and comprising:
means to memorize parameterization of the state of health of a lead-acid battery for different values of battery state of charge, for each of the state of charge values there are values representing the state of health of the battery for pairs of values including battery temperature and a battery parameter which is determined on the basis of measurements of voltage and current taken over a given range of current variation, after the first discharge and during the start-up phase of the vehicle,
means to determine the state of charge of the battery,
means to determine the value representing the state of health of the battery using the parameterization and the pair of values of measured temperature and the parameter deduced from measurements and for the determined state of charge,
and means to provide information on the value representing the state of health of the battery.

For example, an acquisition and processing unit comprises means to determine the start-up capability of the battery in relation to the value representing the state of health, and the information means give information on battery start-up capability.

Advantageously the sensor measuring the current delivered by the battery is of contactless type.

For example, the sensor measuring battery temperature is mounted inside or outside the casing.

Various other characteristics will become apparent from the description given below with reference to the appended drawings which, as non-limiting examples, illustrate embodiments of the subject of the invention.

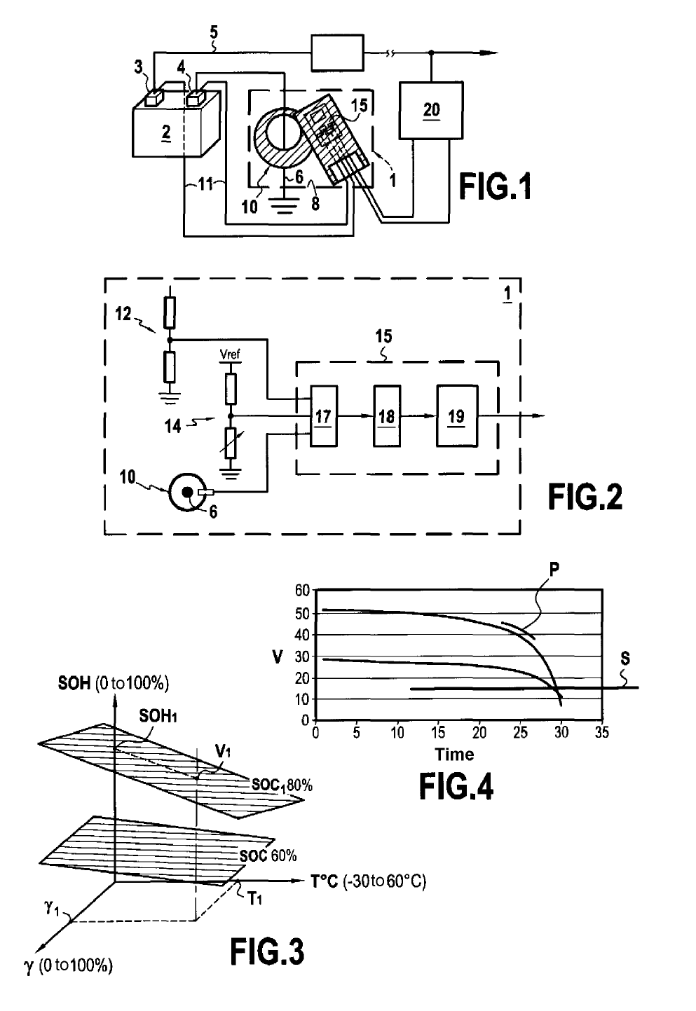

FIG. 1 is a diagram illustrating a battery diagnosis system according to the invention.

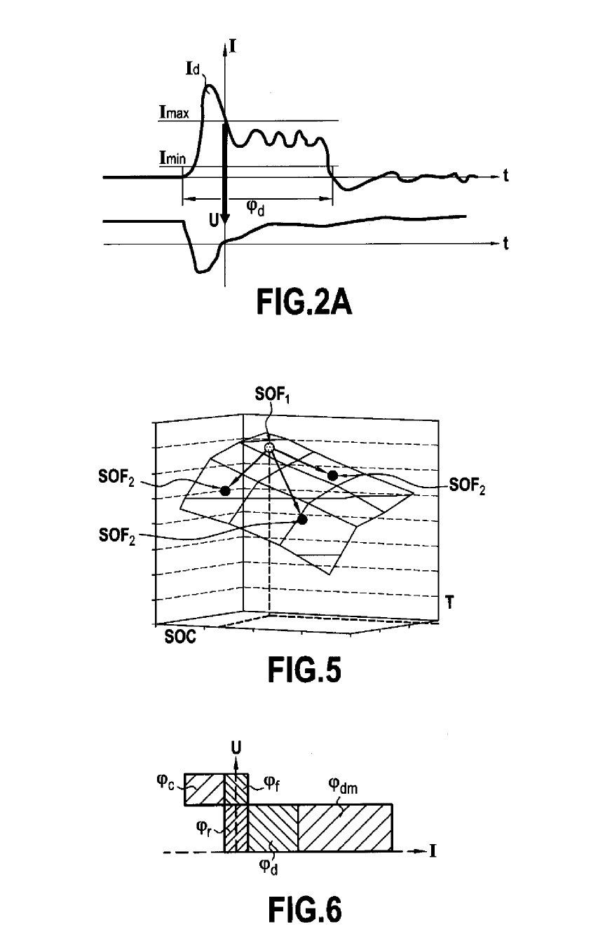

FIG. 2 is a functional diagram of the diagnosis system conforming to the invention.

FIG. 2A is an example of current and voltage curves as a function of time, delivered by a battery during the start-up phase of a vehicle.

FIG. 3 is a three-dimensional illustration explaining the principle of parameterization of the invention.

FIG. 4 illustrates the changes in a value representing the state of health of a battery in relation to successive start-ups.

FIG. 5 illustrates utilization of the measured characteristics of the battery to estimate its start-up capability at the current functioning cycle and to predict its start-up capability in a subsequent state.

FIG. 6 shows means to detect the different operating phases of the vehicle using measurement of current and voltage.

As arises from FIGS. 1 and 2, the subject of the invention concerns a system 1 allowing determination of diagnosis of a battery 2 of lead-acid type equipping an automotive vehicle in the general meaning.

As is conventional, a battery 2 comprises a positive 3 and a negative 4 terminal to which a connection cable 5 and ground cable are respectively connected.

The system 1 is in the form of a casing 8 equipped with assembly means, not shown, allowing its securing preferably onto the cables of the battery. The system 1 comprises a sensor 10 to measure the current I delivered by the battery 2. According to one preferred example of embodiment, the measuring sensor 10 is a magnetic sensor of contactless type mounted around the ground cable 6. For example, the current measuring sensor 10 is of resistive type or of magnetic field type such as a sensor with hall effect, magnetic resistance, GMR or flux gate.

The system 1 is connected to the terminals 3 and 4 via cables 11 and comprises a sensor 12 to measure the voltage U delivered by the battery 2. Evidently, the voltage U delivered by the battery 2 may be measured at a different point to the terminals 3, 4. The system 1 also comprises a sensor 14 to measure the temperature T of the battery 2. Preferably, the sensor 14 measuring temperature is mounted inside the casing 8 making the sensor less sensitive to variations in outside temperature. Evidently, the temperature sensor 14 may be mounted outside the casing 8.

As can be seen more clearly FIG. 2, the system 1 comprises an acquisition and processing unit 15 linked to the sensors measuring current 11, voltage 12 and temperature 14. This unit 15 at its input comprises a multiplexer 17 whose input is connected to the measuring sensors 11, 12 and 14 and whose output is connected to an analog-digital converter 18 connected at its output to a digital processing circuit 19 architectured around a microprocessor associated, as in conventional, with memories and a clock in particular. The digital processing circuit 19 comprises algorithmic means allowing implementation of the method intended to determine diagnosis of the battery 2. Advantageously, this unit 15 comprises means to provide information on diagnosis of the battery to a central management unit 20 associated with the vehicle.

It is to be considered that the method of the invention comprises an experimentation phase which precedes the diagnosis phase properly so-called to diagnose a battery 2 of a vehicle equipped with a system 1 such as described above. According to the invention, the experimentation phase and the diagnosis phase are conducted for the same operating phase of the battery. It is to be noted, that a battery comprises several functioning phases, namely a charge phase φc, a discharge phase φd, start-up phase φdm and a “floating” phase φf i.e. a phase in which the battery is maintained charged in an electric circuit. According to the invention, the diagnosis phase and the experimentation phase are performed for the start-up phase φdm of the vehicle.

In the experimentation phase, the method consists of carrying out parameterization of the state of helath SOH of a lead-acid battery, called an experimentation phase for different values of state of charge SOC of the battery. For example, this experimentation phase uses a battery having the same nominal capacity as the battery 2 to be diagnosed.

For memory, the state of health also called SOH of a battery reflects ageing of the battery. The state of health SOH of a battery is characterized by representative values e.g. corresponding to values of the Ah capacity of the battery or to chemical characteristics of the battery.

According to one preferred characteristic of embodiment, for calculation of the state of health, a distinction is made between the nominal capacity Qn defined as being the capacity when new, and a real capacity Qr which takes ageing into account:

Qr(Ah)=(1% ageing)*Qn(Ah).

This parameterization of the state of health SOH is performed for different values of state of charge also called SOC of the experimentation battery. For memory, the state of charge SOC of a battery corresponds to a percentage of the real capacity of the battery.

For each of the values of the state of charge SOC there are determined values representing the state of health of the battery for pairs of values including battery temperature T and at least one battery parameter γ. Parameter γ is determined on the basis of characteristics of the battery.

According to the subject-matter of the invention, parameter γ is determined from the measurements taken during the start-up phase of the vehicle. As can be seen more clearly FIG. 2A, during the start-up phase φdm and after the first discharge ID, the temperature, current I and voltage U are measured. It is to be noted that the current I and the voltage U are measured over a given range of current variation i.e. between a maximum current value Iₘₐₓ and a minimum current value Iₘᵢₙ. Outside these values Iₘₐₓ and Iₘᵢₙ, the current and voltage values are not taken into account. This is the case for the discharge value Id which corresponds to the first current peak due to capacitive discharge of the battery. This is also the case for the current value close to zero.

After processing, said measurements can be used to deduce a value of parameter γ of the battery.

For example, parameter γ corresponds to:
a considered current value for a threshold voltage value,
a considered voltage value for a threshold current value,
a voltage value corresponding to a peak current value,
a current value corresponding to a peak voltage value,
the ration between a voltage change ΔU and a current fluctuation ΔI,
a ratio between the peak voltage U and current I values,
changes over time in voltage U and current I.

In one particular embodiment, the state of health SOH is defined using two dynamic parameters γ, one with a strong current at the start of discharge to estimate the nominal capacity of the battery, and one with low current at the end of discharge to estimate ageing.

The experimentation phase therefore consists of establishing tables or match matrices giving characteristic values of the state of health SOH of the battery, for different values of the state of charge SOC and for pairs of values of temperature T and parameter γ. FIG. 3 is a three-dimensional graph illustrating the parameterization of the state of health SOH of a battery as a function of temperature T and of parameter γ for different values of the state of charge SOC. For example temperature varies (from −30° C. to 60° C.) whilst the state of charge SOC, the state of health SOH and parameter γ vary over a range of 0 to 100%. Preferably, parameterization is performed by choosing discrete values in appropriate fashion which are then interpolated to obtain a continuous variation in values. In the illustrated example, the state of health SOH is shown for two values of state of charge SOC (namely 60% and 80%) but evidently the state of health SOH can be defined for a higher number of values of state of charge SOC. Therefore the characteristic value V₁ of state of health SOH1 is defined by a value SOC₁ of state of charge for a temperature T₁ and a parameter value γ₁.

The parameterization thus conducted is advantageously memorized in the diagnosis system 1 intended to equip a battery 2 to be monitored.

The system 1 of the invention is adapted to implement a diagnosis phase for which the battery 2 is to be monitored to allow determination of the diagnosis of the battery 2.

The system 1 repeatedly determines the state of charge SOC of the battery. The state of charge SOC of the battery can be determined in any known manner.

According to one preferred characteristic of the invention, the state of charge SOC of the battery is determined from measurements taken during stoppage of the vehicle i.e. with zero current I and from matrices giving the percentage state of charge SOC as a function of pairs of values of voltage U and temperature T.

During the diagnosis phase, the state of charge SOC of the battery is determined when current is zero. Preferably measurements of voltage U and temperature T are performed after a stop time of the vehicle needed for physicochemical stabilization of the battery.

During the diagnosis phase, the method of the invention on several occasions measures the temperature and at least the current and voltage of the battery, and processes the measured values. As explained with reference to FIG. 2A, the measurements of temperature, current and voltage of the battery are recorded for an operating phase of the battery which corresponds to the start-up phase of the vehicle. The measurements are taken as explained above i.e. the current I and voltage U are measured over the range of current variation Iₘₐₓ-Iₘᵢₙ excluding the first current discharge Id. These measurements of the characteristics of the battery are then processed to determine the value of parameter γ.

The method then consists of using the parameterization and on the basis of this value of parameter γ and measured temperature for the determined value of state of charge SOC, to determine the value representing the state of health of the battery 2. According to one variant of embodiment, the method consists of determining the state of health by taking into account the nominal capacity of the battery which is calculated from current-voltage characteristics with high current values whilst percentage ageing is calculated from current-voltage characteristics for low current values. In the example illustrated FIG. 2A, the measurements taken over the range close to value Iₘₐₓ represent the nominal capacity whilst the measurements taken over the range close to value Iₘᵢₙ represent ageing.

According to another variant of embodiment, the method consists of comparing the nominal capacity of the battery with a recommended value so as to deliver an alert signal when the battery shows a nominal capacity lower than the recommended value. This recommended value given by the vehicle manufacturer can be used to alert the vehicle user if an unsuitable battery is mounted on the vehicle.

This value representing the state of health is used to diagnose the battery. This diagnosis can evaluate the functioning capacities of the battery. It is to be noted that the diagnosis method of the invention is performed using solely normal operating characteristics of the battery equipping a vehicle. In particular, the measurements of current I and voltage U correspond directly to the values delivered by the battery which is not connected to an additional utilization source.

According to one preferred characteristic, this diagnosis which gives the value representing the state of health of the battery allows determination of the start-up capability of the battery.

The objective of the method of the invention, after determining battery operating state, is therefore to provide information on the capability of the battery to allow start-up of the vehicle. This predictive diagnosis can therefore alert the vehicle user before failure of the battery.

According to a first example of embodiment, the start-up capability of the battery is determined by recording changes in the value representing the state of health as determined during repetition or succession of the battery operating phase. The method consists of providing information on start-up capability in relation to changes in this representative value V of state of health. As can be seen more clearly FIG. 4, said information is provided either when the value representing state of health reaches a determined threshold value S or when a change exceeds a determination range of variation P.

According to a second example of embodiment, the start-up capability is established from the value of battery parameter γ. Therefore for the value representing state of health and using parameterization, a new value of parameter γ is determined for the value of the measured temperature to which a safety factor is applied and for the determined state of charge SOC to which a safety factor is applied. It effectively appears judicious to take into account a drop in temperature which may occur between the time when the vehicle is stopped and the next start-up (night-time temperature drop). In other words, parameter γ is deduced for the value of the measured temperature to which a safety factor is applied. Similarly in the event of discharge of the battery a safety factor is applied to the determined state of charge SOC. Therefore, using parameterization and for the measured temperature value to which a safety factor is applied and for the determined state of charge SOC to which a safety factor is applied, the value of parameter γ is deduced. In relation to this parameter value γ of the battery, predictive determination can be made of the battery's start-up capability. By way of example, provision may be made to break down the variation range of parameter γ into several zones whether or not these are equal, each corresponding to a different qualification of start-up capability. For example the variation range of parameter γ is broken down into three zones corresponding to low, medium and strong values of parameter γ and for which start-up is considered to be respectively impossible, difficult and problem-free.

As can be seen FIG. 5, determination can be made of a start-up capability SOF₁ corresponding to the current operating cycle and a predictive evaluation of start-up capability SOF₂ which is dependent upon changes in the state of charge SOC and temperature T. Therefore, in the example illustrated FIG. 5, on the basis of start-up capability SOF₁ determination can be made of a start-up capability SOF₂ with reduced SOC, reduced temperature T, and reduced SOC and temperature T.

According to another example of embodiment, the start-up capability of the battery 2 is established by determining a start-up index d which relates to the state of health of the battery for the value of parameter γ and at the measured temperature T.

These indices d are monitored to deduce there from the diagnosis of the battery's start-up capability. In other words, on several occasions during the battery's operating phase a start-up index d is calculated and changes in this index are examined to provide diagnosis of the battery's start-up capability.

The index can be broken down so as preferably to provide information either on problem-free start-up or difficult start-up or impossible start-up.

A further objective of the invention is to propose a method to measure characteristics of the battery according to the operating modes of the battery in the vehicle.

To reach this objective, with this method it is possible to detect the battery's operating phase. As can be more clearly seen FIG. 6, on the basis of measurements of current I and voltage U of the battery, it is possible to determine the various operating phases of the battery namely: charge φc, floating φf, discharge φd, rest φr or start-up φdm.

According to one variant of the invention, during charge or floating the method measures state of charge by coulometry (Ah count) and calculates the temperature of the battery using a thermal model.

According to this same variant, during the rest phase, the sensor measures the no-load voltage of the battery and the method links this with the state of charge. Placing the sensor on standby is activated during this phase, and periodic reactivation is programmed for calculation of state of charge using the no-load voltage, for calculation of the internal temperature of the battery and for prediction of start-up capability SOF₂. Changes in voltage are therefore calculated during this phase. Reactivation of the sensor during this phase is performed after detecting a variation in voltage exceeding a given threshold, or using a LIN network (Local Interconnect Network) of the vehicle or any other communication network.

According to this same variant of the invention, during this discharge phase, the sensor is reactivated and the algorithm calculates state of charge by coulometry, calculates a predictive start-up capability and measures the internal temperature.

According to this same variant of the invention, during the vehicle start-up phase, the method calculates the state of health of the battery, the start-up capability at the current operating cycle SOF₁, calculates the state of charge by coulometry and the internal temperature of the battery using the thermal model.

The invention is not limited to the described, illustrated examples since various modifications may be made thereto without departing from the scope of the invention.

1. Diagnosis method for a lead-acid battery (2) of an automotive vehicle, characterized in that it comprises the following steps:
during an experimentation phase, of conducting parameterization of the state of health (SOH) of a lead-acid battery for different values of the state of charge (SOC) of the battery, for each of the state of charge values there are values representing the state of health of the battery for pairs of values including battery temperature (T) and at least one battery parameter (γ) which is determined from battery voltage (U) and current (I), the temperature (T), current (I) and voltage (U) being measured during the vehicle start-up phase over a given range of current variation and after the first discharge,
during a diagnosis phase of the battery equipping the vehicle:
during the start-up phase of the vehicle, of measuring the temperature of the battery and, after the first discharge and over a given range of current variation, of measuring the corresponding voltage (U) and current (I) so as to deduce, after processing, a parameter value (γ) of the battery,
of determining the state of charge (SOC) of the battery,
and of determining the value representing the state of health of the battery using the parameterization and the pair of values of measured temperature and parameter (γ) deduced from measurements, for the state of charge (SOC), so as to establish a diagnosis of the battery.

2. Method according to claim 1, characterized in that the values representing the state of health correspond to values of the Ah capacity of the battery or to chemical characteristics of the battery.

3. Method according to claim 1, characterized in that the parameter (γ) of the battery is determined from characteristics of the battery such as a considered voltage or current value for a threshold value of current and voltage respectively, a ratio between the peak voltage and current values, a current or voltage value corresponding respectively to a peak voltage or peak current value or to changes over time in voltage and current.

4. Method according to claim 1, characterized in that consists of determining the state of health (SOH) of the battery taking into account the nominal capacity (Qn) of the battery which is calculated from current-voltage characteristics at high current values, whilst the ageing rate is calculated from current-voltage values at low current values.

5. Method according to claim 1, characterized in that it consists of comparing the nominal capacity of the battery with a recommended value so as to deliver an alert signal when the battery shows a nominal capacity lower than the recommended value.

6. System according to claim 1, characterized in that, on the basis of current and voltage measurements, it consists of determining the operating phases of the battery in the vehicle namely charge, floating, discharge, rest or start-up.

7. Method according to claim 1, characterized in that it consists of determining the state of charge (SOC) of the battery from measurements of battery characteristics taken during stoppage of the vehicle, and from matrices giving the percentage state of charge (SOC) in relation to pairs of voltage (U) and temperature (T) values.

8. Method according to claim 7, characterized in that it consists of taking the measurements after a period of vehicle stoppage required for physicochemical stabilization of the battery.

9. Method according to claim 1, characterized in that it consists of determining the start-up capability of the battery in relation to the value representing the state of health.

10. Method according to claim 9, characterized in that it consists of determining the start-up capability of the battery by recording changes in the value representing the state of health as determined during repetition of the operating phase of the battery, and giving information on start-up capability of the battery when the value representing state of health reaches a determined threshold value or when changes exceed a determined range of variation.

11. Method according to claim 9, characterized in that it consists of establishing start-up capability (SOF1) of the battery by determining a start-up index (d) in relation to the state of health of the battery, for the value of parameter (γ) and at the measured temperature (T).

12. Method according to claim 1, comprising the steps of:
for the value representing state of health and by means of the parameterization, of deducing a value of parameter (?) at the value of measured temperature to which a safety factor is applied and at the value of determined state of charge (SOC) to which a safety factor is applied,
and of establishing predictive determination of the start-up capability (SOF2) of the battery in relation to the value of battery parameter (γ) and changes in battery operating conditions.

13. Method according to claim 11, characterized in that it consists of calculating the start-up index (d) on several occasions during the battery operating phase, and of monitoring changes in this index to provide a diagnosis on the battery's start-up capability.

14. Method according to claim 13 characterized in that, in relation to the start-up index, it consists of providing information either on problem-free start-up, or on difficult start-up or one impossible start-up.

15. Method according to claim 14 characterized in that, for a difficult start-up index, it consists of providing information on recommended heating, charging or battery change.

16. Method according to claim 14, additionally comprising, for a difficult start-up index, recommending:
charging the battery if the state of charge (SOC) is low
replacing the battery if the state of charge (SOC) is high

17. System to establish the diagnosis of a lead-acid battery of an automotive motor vehicle, characterized in that in a casing equipped with assembly means it comprises:
a sensor (10) to measure the current (I) delivered by the battery (2)
a sensor (12) to measure the voltage (U) of the battery (2),
a sensor (14) to measure the temperature (T) of the battery (2)
an acquisition and processing unit (15) linked to the measuring sensors and comprising:
means to memorize parameterization of the state of health (SOH) of a lead-acid battery for different values of battery state of charge (SOC), for each of the state of charge values there are values representing the state of health of the battery for pairs of values including battery temperature (T) and a battery parameter (γ) which is determined on the basis of measurements of voltage and current taken over a given range of current variation, after the first discharge and during the start-up phase of the vehicle,
means to determine the state of charge of the battery,
means to determine the value representing the state of health of the battery using the parameterization and the pair of values of measured temperature and the parameter (γ) deduced from measurements and for the determined state of charge (SOC),
and means to provide information on the value representing the state of health of the battery.

18. System according to claim 17, characterized in that the acquisition and processing unit comprises means to establish the start-up capability of the battery in relation to the value representing state of health, and in that the information means give information on the battery's start-up capability.

19. System according to claim 17, characterized in that the sensor (10) measuring current delivered by the battery is of contactless type.

20. System according to claim 17, characterized in that the sensor (14) measuring temperature (T) of the battery is mounted inside or outside the casing.
